(19) United States
(12) Patent Application Publication
(10) Pub. No.: US 2025/0251465 A1
(43) Pub. Date: Aug. 7, 2025

(54) MEASURING A LEAKAGE CURRENT FOR POWER TOKEN ALLOCATIONS

(71) Applicant: Micron Technology, Inc., Boise, ID (US)

(72) Inventors: Leon Zlotnik, Camino, CA (US); Leonid Minz, Beer Sheva (IL)

(21) Appl. No.: 18/888,816

(22) Filed: Sep. 18, 2024

Related U.S. Application Data
(60) Provisional application No. 63/549,955, filed on Feb. 5, 2024.

(51) Int. Cl. G01R 31/52

(52) U.S. Cl. CPC G01R 31/52

(57) ABSTRACT

A method includes determining a temperature and a voltage associated with a system, driving the system into an idle state responsive to determining the temperature and the voltage, measuring a leakage current of the system while in the idle state, associating the temperature and the voltage with the measured leakage current, and allocating a power token based on the temperature, the voltage, and the measured leakage current.

### PRIORITY INFORMATION

This application claims the benefit of U.S. Provisional Application No. 63/549,955, filed on Feb. 5, 2024, the contents of which are incorporated herein by reference.

### TECHNICAL FIELD

Embodiments of the disclosure relate generally to measuring a leakage current for power token allocations, and more specifically, relate to managing power token allocations by compensating for measured leakage current.

### BACKGROUND

Various types of electronic devices such as digital logic circuits and memory systems may store and process data. A digital logic circuit is an electronic circuit that processes digital signals or binary information, which can take on two possible values (usually represented as 0 and 1). The digital logic circuit can use logic gates to manipulate and transform the digital signals or binary information. Digital logic circuits can be, for example, used in a wide range of electronic devices including computers, calculators, digital clocks, and many other electronic devices that employ digital processing. Digital logic circuits can be designed to perform specific logical operations on digital inputs to generate digital outputs, and, in some instances, can be combined to form more complex circuits to perform more complex operations. A memory system can include one or more memory devices that store data, a digital logic, and an associated power token allocation control. The memory devices can be, for example, non-volatile memory devices and volatile memory devices. In general, a host system can utilize a memory system to store data at the memory devices and to retrieve data from the memory devices and the power token control can allocate power tokens during operation of the digital logic.

### BRIEF DESCRIPTION OF THE DRAWINGS

The present disclosure will be understood more fully from the detailed description given below and from the accompanying drawings of various embodiments of the disclosure.

FIG. 1 illustrates an example computing system that includes a memory system in accordance with some embodiments of the present disclosure.

FIG. 2 illustrates an example of an apparatus including power token allocation circuitry in accordance with some embodiments of the present disclosure.

FIG. 3 illustrates an example method diagram for power token allocation in accordance with some embodiments of the present disclosure.

FIG. 4 is a block diagram of an example computer system in which embodiments of the present disclosure may operate.

### DETAILED DESCRIPTION

Aspects of the present disclosure are directed to measuring leakage current for power token allocations, in particular circuitry (e.g., power token allocation circuitry) to perform allocation of static and dynamic power tokens. The static power tokens and the dynamic power tokens can form a total power resource pool of the system. Static and dynamic power token allocations can be used to match system power consumption with desired performance. Temperature or a combination of voltage and temperature associated with a system (e.g., a computing system) can be monitored to determine power token allocation. As such, power token allocation is a technique that aims at increasing efficiency and reducing the power consumption of a system by adjusting power tokens allocated to devices within the system.

Although some non-limiting examples herein are generally described in terms of applicability to memory systems and/or to memory devices, embodiments are not so limited, and aspects of the present disclosure can be applied as well to systems such as computer systems. The embodiments describe can be applicable to a system-on-a-chip, computing sub-system, data collection and processing, storage, networking, communication, power, artificial intelligence, control, telemetry, sensing and monitoring, digital entertainment, and other types of systems/sub-systems and/or devices where resources are allocated. Accordingly, aspects of the present disclosure can be applied to these components in order to allocate resources where the allocation of resources includes the calculation of static resource and dynamic resources, as described herein.

A system can provide resources to devices of the system or devices external to the system. As used herein, resources (e.g., system resources) can include power resources among other types of resources such as processing resources, for example. A device can request power from the system to perform operations. Power from the resources can be allocated based on requests, availability, and/or priority, among other considerations. The device can utilize the power to, for example, write data, read data, transfer data via an input/output (I/O) bus, and/or transfer data via an interface that couples the system (e.g., memory system) to a different system (e.g., host).

During operation of the computing system, a resource manager of the system can assign or allocate power tokens to a device of the system to perform a task or tasks associated with the processing device. Power tokens may be allocated responsive to a device request for power from the system. A budget or pool of power (i.e., total amount of available power) can include a plurality of static and dynamic power tokens in order for power to be allocated to different devices of the system. The temperature and/or a voltage of the system can cause a current of the system to leak and/or an amount of leakage to vary. As used herein, leakage describes the unavailability of a resource for performing operations. The resources allocated to a device that are available to the device for performing operations are referred to as dynamic resources. Resources allocated to the device that are not available to the device for performing operations are referred to as static resources. A current leakage can be referred to as a static resource. To compensate for the leakage current, the resource manager can allocate more static power tokens. In some scenarios, the allocated power may represent more power than the device utilizes to complete the task or tasks. Once the task or tasks are completed and the device is no longer utilizing power allocated in the power token, the power token can be returned to the pool. However, when the plurality of power tokens is allocated and the pool is depleted, further devices requesting power to perform a task or tasks may have to wait until a power token or tokens are returned to the pool to be allocated back out by the resource manager. Accordingly, the system may have insufficient resources, at least in some instances, to satisfy the resource (e.g., power) demands of all devices.

Further, during operation of the computing system, the system can experience a decrease or an increase in the amount of leakage current based on an attribute of the system. For example, attributes of the system may include changes such as temperature and/or voltage associated with the environment, system, age of the system, and/or utilization or workload of the system, etc. For instance, the higher the temperature associated with the system the greater the leakage current experienced in the system. Because electrical current is utilized to provide power to the system, the system can exhibit temperature fluctuations during operation. Such fluctuations can become more pronounced based on the type of workload the system is subject to. For example, some types of workloads that can be characterized by high volumes of operations can give rise to greater temperature fluctuations within the system than workloads that are characterized by low volumes of operations, resulting in a higher leakage current. Further, a system can experience temperature fluctuations based on the environment in which the system is deployed. Additionally, over time and use, the quality of the system can degrade requesting adjustments that contribute to temperature and workload changes.

Further, power in such systems can be provided by various power supplies, which generally supply a voltage signal or current signal to one or more voltage regulators. The voltage regulator(s) then seek to maintain a stable output voltage and provide the stable output voltage to various components of the system. Generally, the voltage regulator(s) are able to maintain and provide the stable output voltage under normal operating conditions of the system; however, due to various factors such as process variation in components, operational conditions of the system, and/or sudden changes in loads experienced by components during operation of the system, among other factors, the voltage regulator(s) can sometimes temporarily fail to supply a stable voltage to components of the system.

Additionally, the system may have a nominal voltage setting that includes dynamic voltage scaling. Dynamic voltage scaling to increase voltage can be referred to as overvolting, whereas dynamic voltage scaling to decrease voltage can be referred to as undervolting. Undervolting can be performed in order to conserve power, particularly in computing systems such as laptops and other mobile devices, where energy comes from a battery and thus is limited, or, in some cases, to increase reliability of a computing system. The higher the voltage supplied to the system the higher the leakage current experienced.

In some cases, to ensure that an adequate supply of power tokens is allocated to compensate for leakage current, the system may be set to allocate static power tokens according to a worst case scenario (e.g., approximate highest expected supplied voltage, approximate highest expected temperature, etc.). A system that does not monitor fluctuations in voltage and/or temperature may continuously allocate power tokens based on the worst case scenario. For example, even in scenarios in which a supplied voltage is lower than the highest expected voltage and/or the temperature is lower than the highest expected temperature, the system may continue to allocate power tokens based on a highest expected supplied voltage and/or highest expected temperature scenario. Thus, at times the allocated power tokens may exceed the tokens utilized by the device.

For example, the leakage current may be less than the worst case scenario and therefore power may be allocated to a set of static power tokens that is greater than what is lost due to leakage current. Accordingly, a total amount of power, including static and dynamic power tokens, allocated may exceed what is utilized by the processing device. Put another way, in this scenario, power may be allocated according to a potential worst case leakage even in cases that are not worst case, thus since the actual leakage current may be less than what was allocated toward leakage (i.e., static power token(s)) the resource manager may allocate more resources to the device than needed. Allocating more resources than needed utilizes resources that could be allocated elsewhere (e.g., to waiting processing devices), incurring reduced overall efficiency of the system. Though fluctuations in temperature or supplied voltage are discussed, examples are not so limited and other factors, such as age of the device, utilization or workload of the device, etc. may contribute to an amount of current leakage.

Aspects of the present disclosure address the above and other deficiencies by providing power token allocation circuitry that receives information from various voltage sensors, current sensors, and/or temperature sensors in the system and sends signals to a resource manager to cause the resource manager to allocate static and dynamic power tokens. The power tokens may be allocated based on a leakage current associated with an amount of voltage supplied to the system and/or a temperature associated with the system to reduce power consumption within a system without negatively impacting performance of devices.

For example, some embodiments herein, prior to allocating a power token, determine an amount of voltage supplied to the system and determine a measured temperature associated with the system. Responsive to the measured temperature and the amount of voltage supplied being associated and stored in a data structure within a threshold period, some embodiments determine a leakage current associated to the amount of voltage supplied and the measured temperature (i.e., stored in the data structure and corresponding to the voltage supplied and the measured temperature) and allocate a power token based on the associated leakage current. Further, responsive to the measured temperature not being associated to the amount of voltage supplied and stored in the data structure and/or not associated within the threshold period, some embodiments drive the system into an idle state, measure a leakage current of the system, associate the measured leakage current with the amount of voltage supplied and the measured temperature, drive the system into an active state, and allocate the power token based on the associated measured leakage current. Measurements of the voltage supplied to the system, the temperature associated with the system, the measured leakage current of the system, and a date and time can be stored in memory, register, arrays, storage devices, and/or files of any type and can be copied to different memory, registers, arrays, storage devices, and/or files of any type. In some embodiments, in a non-limiting example, the data structure may be a database and/or a look-up table.

As voltages and temperatures associated with the system fluctuate, leakage current encountered by the system can fluctuate causing the quantity of power tokens requested to perform a task or tasks to change (e.g., increase or decrease). Accordingly, each allocation of power tokens may reflect differing leakage current. As such, allocated power tokens may be based on a particular voltage and/or a particular temperature of a particular device of the system and each device may exhibit differing leakage currents based on the device (e.g., tolerances of the device, utilization of the device, age of the device, etc.). As a result, allocated different number of power tokens may thus refer to a differing wattage or power values based on the leakage current associated with a particular voltage and/or a particular temperature, thus increasing efficiency and power consumption of the system. That is, embodiments herein may allocate less static power tokens at lower temperatures and lower voltages. Allocation of less static power tokens can allow for more dynamic power tokens to be granted thus, increasing the efficiency and performance of the system utilizing the same power consumption.

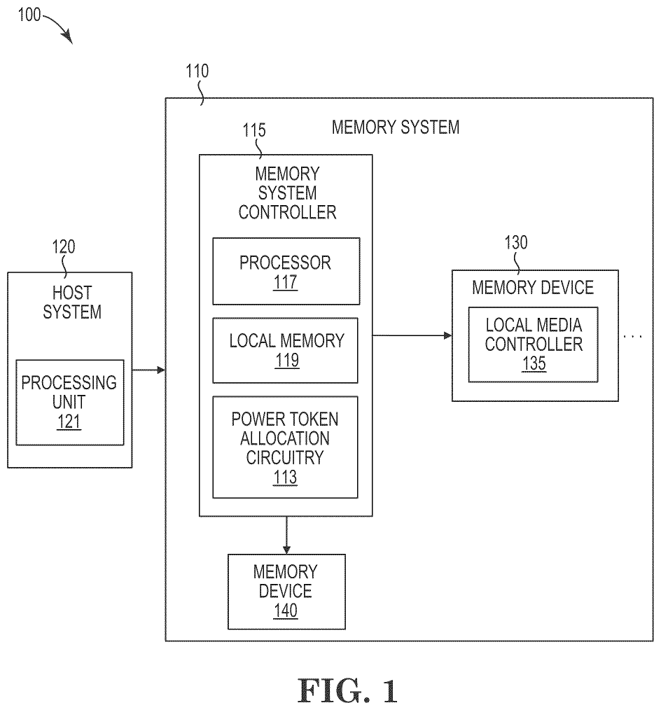

FIG. 1 illustrates an example computing system 100 that includes a memory system 110 in accordance with some embodiments of the present disclosure. The memory system 110 can include media, such as one or more volatile memory devices (e.g., memory device 140), one or more non-volatile memory devices (e.g., memory device 130), or a combination of such.

A memory system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, server, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

In other embodiments, the power token allocation circuitry 113 can be deployed on, or otherwise included in a computing device such as a desktop computer, laptop computer, server, network server, mobile computing device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device. As used herein, the term “mobile computing device” generally refers to a handheld computing device that has a slate or phablet form factor. In general, a slate form factor can include a display screen that is between approximately 3 inches and 5.2 inches (measured diagonally), while a phablet form factor caninclude a display screen that is between approximately 5.2 inches and 7 inches (measured diagonally). Examples of “mobile computing devices” are not so limited, however, and in some embodiments, a “mobile computing device” can refer to an IoT device, among other types of edge computing devices.

The computing system 100 can include a host system 120 that is coupled to one or more memory systems 110. In some embodiments, the host system 120 is coupled to different types of memory system 110. FIG. 1 illustrates one example of a host system 120 coupled to one memory system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, and the like.

The host system 120 can include a processor chipset and a software stack executed by the processor chipset. The processor chipset can include one or more cores, one or more caches, a memory controller (e.g., an SSD controller), and a storage protocol controller (e.g., PCIe controller, SATA controller). The host system 120 uses the memory system 110, for example, to write data to the memory system 110 and read data from the memory system 110.

The host system 120 includes a processing unit 121. The processing unit 121 can be a central processing unit (CPU) that is configured to execute an operating system. In some embodiments, the processing unit 121 comprises a complex instruction set computer architecture, such an x86 or other architecture suitable for use as a CPU for a host system 120.

The host system 120 can be coupled to the memory system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), Small Computer System Interface (SCSI), a double data rate (DDR) memory bus, a dual in-line memory module (DIMM) interface (e.g., DIMM socket interface that supports Double Data Rate (DDR)), Open NAND Flash Interface (ONFI), Double Data Rate (DDR), Low Power Double Data Rate (LPDDR), or any other interface. The physical host interface can be used to transmit data between the host system 120 and the memory system 110. The host system 120 can further utilize an NVM Express (NVMe) interface to access components (e.g., memory devices 130) when the memory system 110 is coupled with the host system 120 by the PCIe interface. The physical host interface can provide an interface for passing control, address, data, and other signals between the memory system 110 and the host system 120. FIG. 1 illustrates a memory system 110 as an example. In general, the host system 120 can access multiple memory systems via the same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random-access memory (DRAM) and synchronous dynamic random access memory (SDRAM).

Some examples of non-volatile memory devices (e.g., memory device 130) include negative-and (NAND) type flash memory and write-in-place memory, such as three-dimensional cross-point (“3D cross-point”) memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130, 140 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLC) can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as three-dimensional cross-point arrays of non-volatile memory cells and NAND type memory (e.g., 2D NAND, 3D NAND) are described, the memory device 130 can be based on any other type of non-volatile memory or storage device, such as such as, read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

The memory system controller 115 (or controller 115 for simplicity) can communicate with the memory devices 130 to perform operations such as reading data, writing data, or erasing data at the memory devices 130 and other such operations. The memory system controller 115 can include hardware such as one or more integrated circuits and/or discrete components, a buffer memory, or a combination thereof. The hardware can include digital circuitry with dedicated (i.e., hard-coded) logic to perform the operations described herein. The memory system controller 115 can be a microcontroller, special purpose logic circuitry (e.g., a field programmable gate array (FPGA), an application specific integrated circuit (ASIC), etc.), or other suitable processor.

The memory system controller 115 can include a processor 117 (e.g., a processing device) configured to execute instructions stored in a local memory 119. In the illustrated example, the local memory 119 of the memory system controller 115 includes an embedded memory configured to store instructions for performing various processes, operations, logic flows, and routines that control operation of the memory system 110, including handling communications between the memory system 110 and the host system 120.

In some embodiments, the local memory 119 can include memory registers storing memory pointers, fetched data, etc. The local memory 119 can also include read-only memory (ROM) for storing micro-code. While the example memory system 110 in FIG. 1 has been illustrated as including the memory system controller 115, in another embodiment of the present disclosure, a memory system 110 does not include a memory system controller 115, and can instead rely upon external control (e.g., provided by an external host, or by a processor or controller separate from the memory system).

In general, the memory system controller 115 can receive commands or operations from the host system 120 and can convert the commands or operations into instructions or appropriate commands to achieve the desired access to the memory device 130 and/or the memory device 140. The memory system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address, physical media locations, etc.) that are associated with the memory devices 130. The memory system controller 115 can further include host interface circuitry to communicate with the host system 120 via the physical host interface. The host interface circuitry can convert the commands received from the host system into command instructions to access the memory device 130 and/or the memory device 140 as well as convert responses associated with the memory device 130 and/or the memory device 140 into information for the host system 120.

The memory system 110 can also include additional circuitry or components that are not illustrated. In some embodiments, the memory system 110 can include a cache or buffer (e.g., DRAM) and address circuitry (e.g., a row decoder and a column decoder) that can receive an address from the memory system controller 115 and decode the address to access the memory device 130 and/or the memory device 140.

In some embodiments, the memory device 130 includes local media controllers 135 that operate in conjunction with memory system controller 115 to execute operations on one or more memory cells of the memory devices 130. An external controller (e.g., memory system controller 115) can externally manage the memory device 130 (e.g., perform media management operations on the memory device 130). In some embodiments, a memory device 130 is a managed memory device, which is a raw memory device combined with a local controller (e.g., local controller 135) for media management within the same memory device package. An example of a managed memory device is a managed NAND (MNAND) device.

The memory system 110 can also include power token allocation circuitry 113. Although not shown in FIG. 1 so as to not obfuscate the drawings, the power token allocation circuitry 113 can include various circuitry to facilitate aspects of the disclosure described herein. In some embodiments, the power token allocation circuitry 113 can include special purpose circuitry in the form of an ASIC, FPGA, state machine, hardware processing device, and/or other logic circuitry that can allow the power token allocation circuitry 113 to orchestrate and/or perform operations to provide dynamic power token allocation, particularly with respect to a system-on-chip, in accordance with the disclosure. In various instances, the power token allocation circuitry 113 can be external to the memory system controller 115.

In some embodiments, the memory system controller 115 includes at least a portion of the power token allocation circuitry 113. For example, the memory system controller 115 can include a processor 117 (processing device) configured to execute instructions stored in local memory 119 for performing the operations described herein. In some embodiments, the power token allocation circuitry 113 is part of the host system 120, an application, or an operating system. The memory system power token allocation circuitry 113 can be resident on the memory system 110. As used herein, the term “resident on” refers to something that is physically located on a particular component. For example, the memory system power token allocation circuitry 113 being “resident on” the memory system 110 refers to a condition in which the hardware circuitry that comprises the memory system power token allocation circuitry 113 is physically located on the memory system 110. The term “resident on” can be used interchangeably with other terms such as “deployed on” or “located on,” herein.

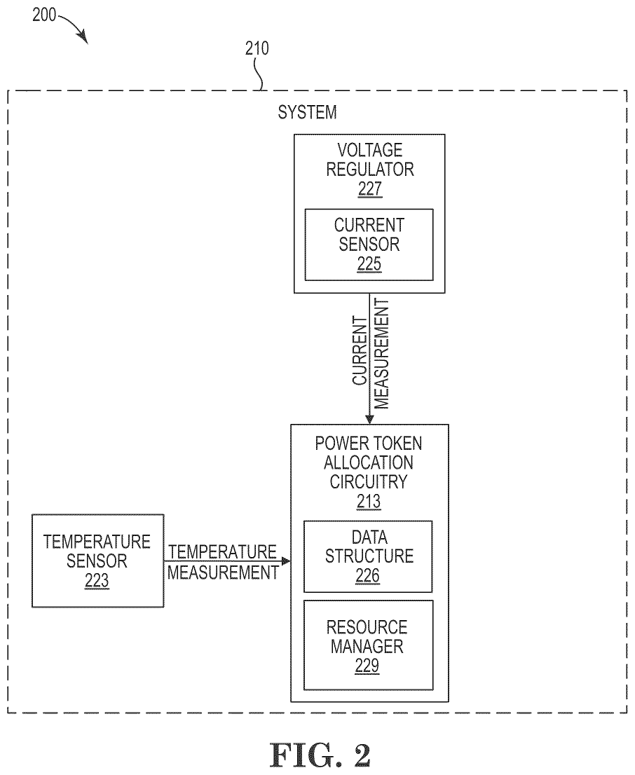

FIG. 2 illustrates an example of an apparatus 200 including power token allocation circuitry 213 in accordance with some embodiments of the present disclosure. The power token allocation circuitry 213 can be utilized to allocate power tokens to a system 210 based on a leakage current associated with an amount of voltage supplied to and a measured temperature associated with the system 210. Although non-limiting examples herein are generally described in terms of applicability to memory system and/or to memory devices (e.g., the memory devices 130, 140 of FIG. 1), embodiments are not so limited, and aspects of the present disclosure can be applied as well to a system-on-a-chip, computing system/sub-system, data collection and processing, storage, networking, communication, power, artificial intelligence, control, telemetry, sensing and monitoring, digital entertainment and other types of system and/or devices. Accordingly, aspects of the present disclosure can be applied to these components in order to provide for measuring a leakage current for power token allocations, as described herein.

For example, the power token allocation circuitry 213 can be coupled to a voltage regulator 227. The voltage regulator 227 can be utilized to regulate the amount of voltage supplied to the system 210. The voltage regulator 227 may be utilized to increase or decrease the amount of voltage supplied dependent on uses and/or usage of the system 210 (e.g., in the case of overvolting, undervolting, etc.).

In some embodiments, the power token allocation circuitry 213 can be coupled to a temperature sensor 223. The temperature sensor 223 can be utilized to measure and/or monitor a temperature associated with the system 210 of the apparatus. For example, the temperature sensor 223 can measure the temperature of the system 210 or a portion of the system 210. The temperature sensor 223 may perform a number of operations on the measured temperature(s) including taking a number of measurements of the temperature and averaging the temperature prior to providing the temperature to the system 210. The temperature sensor 223 can include hardware and/or firmware configured to measure a temperature and provide the temperature to the power token allocation circuitry 213. In some embodiments, multiple temperature sensors may be utilized and may monitor temperatures throughout the system 210 (e.g., measuring temperatures at/of different devices).

The power token allocation circuitry 213 can be further coupled to a current sensor 225. The current sensor 225 can be utilized to measure a leakage current of the system 210. The current sensor 225 can include hardware and/or firmware configured to measure a leakage current and provide the leakage current to the power token allocation circuitry 213. In some embodiments, multiple current sensors may be utilized to monitor leakage current throughout the system 210 (e.g., measuring leakage current to different devices).

In some embodiments, the power token allocation circuitry 213 may include a processor (not shown). A data structure 226 may be coupled to the processor, the power token allocation circuitry 213, in a local memory (e.g., the local memory 119 of FIG. 1), and/or memory devices (e.g., the memory devices 130, 140 of FIG. 1), among other locations. In various instances, the memory device that stores the data structure 226 can be separate from the processor, the power token allocation circuitry 213, local memory, and/or the memory devices but may be implemented in the system 210. The memory that stores the data structure 226 can also be implemented external to the system 210, such as in a host system (e.g., the host system 120 of FIG. 1).

The processor may be coupled to the voltage regulator 227, the temperature sensor 223, and the current sensor 225 and may be configured to manage the data structure 226 in which a voltage, a temperature, and a leakage current may be recorded. For example, the voltage regulator 227 may regulate an amount of voltage supplied to a system, the temperature sensor 223 (or sensors) may measure a temperature associated with the system, the current sensor 225 (or sensors) may measure a leakage current of the system, and the processor may be configured to associate the amount of voltage supplied and the measured temperature with the measured leakage current. Further, the processor may be configured to store the measured leakage current associated with the amount of voltage supplied and the measured temperature in the data structure 226. In some embodiments, the processor may determine a date and a time at which the leakage current was measured and associated with the amount of voltage supplied and the measured temperature; associate the date and the time with the amount of voltage supplied, measure temperature, and measured leakage current; and store the date and the time in the data structure 226.

In various instances, as previously described, the processor may be part of the power token allocation circuitry 213. The power token allocation circuitry 213 can track historical data from temperatures provided by the temperature sensor 223 and leakage currents provided by the current sensor 225 and can predict a future temperature and/or leakage current. The power token allocation circuitry 213 can be coupled to a resource manager 229. In some embodiments, the resource manager 229 can be utilized to allocate resources to devices of the system 210. For example, the resource manager 229 can be utilized to allocate both static power tokens and dynamic power tokens supplied to the system 210 and/or the devices of the system 210. In some embodiments, the resource manager 229 can allocate a power token (or tokens) based on the stored voltage, temperature, leakage current, and/or the date and times the voltage, temperature, and leakage current were stored in the data structure 226.

The examples provided herein are given under the assumption that the devices requiring resources are powered (e.g., not gated). If the system 210 contains different power domains, a separate leakage current, supplied voltage, and measured temperature association can be stored for each of the domains. As used herein, a domain (e.g., power domain) can include gated devices, and/or devices having different voltages, for example. The resource manager 229 can allocate static tokens and dynamic tokens separately for different types of domains. The power token allocation circuitry 213 can be aware of the minimum quantity of power tokens that can be allocated to devices having different power domains. For example, a gated device that is powering on can request total resources that comprise static and dynamic resources. The resource manager 229 may not allocate less than a particular quantity of static resources to the requesting device. Un-gating of the device may utilize some static power tokens. The power token allocation circuitry 213 can access a leakage current based on the voltage of the device, the temperature of the device, and whether the device is gated or not (e.g., a power domain of the device). Though a device requesting resources is described it is further contemplated that the power token allocation circuitry 213 may access a data structure (similar to or within data structure 226) to determine resources required to operate the device or the system 210 itself may decide how to divide power tokens.

Responsive to a device request for resources, in some embodiments, the power token allocation circuitry 213 of the system 210 may be configured to determine the amount of voltage supplied to the system 210 by the voltage regulator 227. The power token allocation circuitry 213 may be further configured to compare the amount of voltage supplied to the system 210 to voltage values stored in the data structure 226. In some cases, the amount of voltage supplied to the system 210 may be stored in the data structure 226 (e.g., per a default setting or previously determined and stored).

In other cases, the amount of voltage supplied to the system 210 may closely match what is stored in the data structure 226 but may not be an exact match. As such, as used herein, “matching” refers to a value that is a within a minimal distance or a threshold value from a value stored in the data structure 226. For example, in some scenarios the voltage supplied may match (or closely match, within the threshold) a voltage stored in the data structure 226 (e.g., as non-limiting examples, 0.01V, 0.02V difference between the voltage supplied and the stored voltage, or within a 0.03V threshold, etc.). It is to be noted that, in some cases, the threshold value of voltage difference (between the voltage supplied and a stored voltage value) may remain consistent no matter what the supplied voltage value may be. However, a lower voltage supplied can affect the amount of leakage current encountered differently than a higher voltage supplied. For example, the higher the voltage supplied, the higher the leakage current encountered. Further, increases and decreases in leakage current due to fluctuations in the voltage supplied may not be linear and thus, to compensate for this non-linear leakage current value the threshold value of voltage difference may also be non-linear.

One way to compensate for a minimal difference between the voltage supplied to the system and a voltage value stored in the data structure 226 that lies within a threshold value, may be to round the voltage supplied to the nearest voltage value stored in the data structure 226. As an example, a voltage may be measured and determined to be 0.75V. The determined voltage of 0.75V may be compared to voltage values stored in the data structure 226. In the case where 0.75V is not in the data structure 226 but a voltage value of 74V is in the data structure 226, the power token allocation circuitry 213 may be configured to select the 0.74V value in the data structure 226.

In other cases, when the voltage supplied closely matches the voltage stored in the data structure 226 (e.g., within the threshold value), the voltage supplied to the system may fall between two voltage values stored in the data structure 226. For example, a voltage value of 0.74V and a voltage value of 0.78 V may both be stored in the data structure 226. In a scenario where the voltage supplied to the system is 0.76V (i.e., within the threshold value of 0.74V and 0.78V) and the measure temperature is a particular temperature that is a temperature associated in the data structure 226 to both the 0.74V and 0.78V values, interpolation may be implemented. For example, an interpolated value lying between 0.74V and 78V that closely matches a 0.76V value may be calculated. In some cases, interpolation may include a linear function of the 0.74V and the 0.78V values. In other cases, interpolation between the 0.74V and 0.78V values may include a non-linear function to compensate for increases and/or decreases in the voltage supplied, as will be further described herein. As such, in some cases as further described herein, based on the measured temperature and the utilization of interpolation for the supplied voltage, the leakage current for a voltage of 0.76V may be calculated.

In yet another case, a minimal difference (e.g., within the threshold value) in the voltage supplied compared to the voltage stored may result in the voltage supplied to the system falling just outside of or closely matching one voltage value stored in the data structure 226. For example, voltage values of 0.74V, 0.77V, and 0.8V may be stored in the data structure 226. In a case where the voltage supplied to the system is 0.82 V, the 0.82V may not be stored in the data structure 226. However, the measured temperature may be a particular temperature that is a temperature associated in the data structure 226 to the 0.8V and the supplied voltage of 0.82V may be within the threshold value from the 0.8V stored in the data structure 226. As such, extrapolation may be implemented to calculate a leakage current value corresponding to 0.82V. As such, in some cases as further described herein, based on the measured temperature and the utilization of extrapolation for the voltage supplied, the leakage current for a voltage of 0.82V may be calculated.

Further, in some cases, the data structure 226 may include zones of voltages. In some cases, where the threshold value of voltage difference remains consistent no matter what the supplied voltage value may be, each zone may be the same width (i.e., may be linear). For example, a first zone may include voltage values of 0.74V-0.769V, a second zone may include voltage values of 0.77V-0.799V, a third zone may include voltage values of 0.8V-0.829V, and so forth. As such, in the scenario where the voltage supplied is 0.742V the table corresponding to the first zone (i.e., the 0.74V-0.769V table) may be selected and in the scenario where the voltage supplied is 0.782V the table corresponding to the second zone (i.e., the 0.77V-0.799V table) may be selected.

However, to compensate for increases and/or decreases in leakage current that may be non-linear due to fluctuations in the voltage supplied, the threshold value of voltage difference may also be non-linear. In this case, voltage zones (i.e., tables in the data structure 226) may be non-linear in width. For example, potential supplied voltage values between 0.70V-0.749V may have a threshold value of voltage difference or a zone width of 0.025V (i.e., voltage values within a zone and/or table within the data structure 226). Thus, the 0.025V threshold may dictate the width of each zone between 0.70V and 0.749V and as such, a first voltage zone may be 0.70V-0.724V and a second voltage zone may be 0.725V-0.749V. Potential supplied voltage values between 0.75V-0.799V may have a threshold value of voltage difference or a zone width of 01V. Thus, the 0.01V threshold may dictate the width of each zone between 0.75V and 799V and as such, a third voltage zone may be 0.75V-0.759V, a fourth voltage zone may be 0.76V-0.769V, a fifth voltage zone may be 0.77V-0.779V, a sixth voltage zone may be 0.78V-0.789V, and a seventh voltage zone may be 0.79V-0.799V. A potential of supplied voltage values between 0.8V-0.819V may have a threshold value of voltage difference or a zone width of 0.005V. Thus, the 0.005V threshold may dictate the width of each zone between 0.8V and 0.819V and as such, an eighth voltage zone may be 0.8V-0.804V, a ninth voltage zone maybe 0.805V-0.809V, a tenth voltage zone may be 0.81V-0.814V, and an eleventh voltage zone may be 0.815V-0.819V. As such, in the scenario where the voltage supplied is 0.742V the table corresponding to the second zone (i.e., the 0.725V-0.749V table) may be selected and in the scenario where the voltage supplied is 0.782V the table corresponding to the sixth zone (i.e., the 0.78V-0.789V table) may be selected.

As such, as used herein, a voltage supplied may be considered significantly different than a voltage value stored in the data structure 226 when the voltage supplied is outside of or greater than a threshold value of voltage difference from a stored voltage value.

However, in some cases, the amount of voltage supplied to the system 210 may not have been previously stored in the data structure 226 and/or may be significantly different (i.e., outside of the threshold value of voltage difference) than voltage values stored in the data structure 226. As such, the power token allocation circuitry 213 may be further configured to determine the measured temperature associated with the system 210, associate the determined amount of voltage supplied to the system 210 to the measured temperature, and store the determined amount of voltage supplied and the measured temperature in the data structure 226.

As an example, a voltage may be measured and determined to be 0.74V. The measured voltage of 0.74V may be compared to voltage values stored in the data structure 226. In the case where 0.74V is not in the data structure 226 and/or not within a zone or a threshold value of voltage difference from voltage values stored in the data structure 226, the power token allocation circuitry 213 may be configured to associate the measured voltage to the measured temperature and store the measured voltage and the measured temperature in the data structure 226. As is described in further detail herein, the power token allocation circuitry 213 may be configured to further associate a measured leakage current with the measured voltage and associated measured temperature.

As stated above, the voltage may fluctuate over time and operation of the system 210 (e.g., increase or decrease dependent on variations in the system 210 and/or the circuitry). The power token allocation circuitry 213 may be configured to monitor the amount of voltage supplied to the system 210 to detect a change (e.g., an increase or a decrease) in the amount of voltage supplied. Responsive to a detection of change in the amount of voltage supplied, the power token allocation circuitry 213 may be configured to determine whether the detected change in the amount of voltage supplied is a significant change that exceeds a threshold amount of voltage change. Responsive to determining that the change in the amount of voltage supplied exceeds the threshold amount of voltage change, the power token allocation circuitry 213 may be configured to compare the amount of voltage supplied to the system 210 to voltage values stored in the data structure 226. For example, a 0.03V fluctuation may be set as a threshold amount of voltage change, though examples are not so limited and various voltage values and/or ranges may be set (as one example, the 0.025V, 0.01V, and 0.005V in the example where the threshold value of voltage difference is non-linear).

In various instances, the monitored voltage can be utilized to select a table in the data structure 226. As previously described, rounding, interpolation, extrapolation, and/or zones may be implemented in the event that the detected voltage supplied closely matches a voltage table in the data structure 226. Utilizing the example voltage tables previously described, if the voltage supplied was 0.74V and the table corresponding to the 0.74V, the linear zone corresponding to 0.74V-0.76V, or the non-linear zone corresponding to 0.725V-0.749V was selected in the data structure 226 and the voltage supplied increased to 0.78V, exceeding the threshold amount of voltage change, the power token allocation circuitry 213 may be configured to round the voltage supplied value and select the table corresponding to 0.77V; determine the value for a supplied voltage of 0.78V utilizing interpolation between the 0.77V table and the 0.8V table; in the case of linear zones, select the voltage zone of 0.77V-0.799V; or in the case of non-linear zones, select the voltage zone of 0.77V-0.779V. However, if the voltage supplied increased to 0.81V, the power token allocation circuitry 213 may be configured to round the voltage supplied value and select the table corresponding to 0.8V; determine the value for a supplied voltage of 0.81V utilizing extrapolation from the 0.8V table; in the case of linear zones, select the voltage zone of 0.8V-0.829V; or in the case of non-linear zones, select the voltage zone of 0.815V-0.819V. Although three voltage values, three linear voltage zones, and eleven non-linear voltage zones are described throughout the disclosure, the scope of the disclosure further contemplates the usage of other quantities of voltage values, linear voltage zones, and/or non-linear voltage zones to provide additional fine tuning to the voltage value and/or zone that is selected and/or utilized.

The voltage regulator 227 of the system 210 and/or a voltage control circuitry of the system 210 can provide the voltage supplied to the system 210 to the power token allocation circuitry 213. As described, the voltage amount can be utilized to select a voltage table in the data structure 226. The table can be selected based on the amount of voltage supplied by the system 210 and can be associated with a temperature or various temperatures associated with the system 210. Put another way, the data structure 226 can include a plurality of temperatures corresponding to a plurality of voltages, as will be further described herein. As one example, the table selected based on supplied voltages between 0.74V-0.769V may include temperatures ranging from 60 degrees to 130 degrees, the table selected based on supplied voltages between 0.77V-0.799V may include temperatures ranging from 40 degrees to 130 degrees, the table selected based on supplied voltages between 0.8V-0.829V may include temperatures ranging from 25 degrees to 130 degrees, and so forth. Though temperatures of 25 to 130 degrees are described in these examples, temperatures below 25 degrees are also contemplated.

In some cases, the amount of voltage supplied to the system 210 may be a voltage value stored in the data structure 226 (e.g., closely matching in the case of rounding, calculated based on extrapolation and/or interpolation, or being within a voltage zone, etc.). As such, the power token allocation circuitry 213 may be configured to compare the measured temperature, measured by the temperature sensor 223, to temperatures associated with the voltage value stored in the data structure 226. Put another way, responsive to the amount of voltage supplied matching (i.e., closely matching) a voltage value stored in the data structure 226, a table corresponding to the amount of voltage supplied may be selected and the measured temperature may be compared to temperatures listed in the selected table.

In some cases, the measured temperature of the system 210 may be stored in the data structure 226 (e.g., per a default setting or previously determined and stored). In other cases, the measured temperature of the system 210 may closely match what is stored in the data structure 226 but may not be an exact match. As previously described, the term “matching” refers to a value that is within a minimal value or a threshold value from a value stored in the data structure 226. As will be further described herein, in some cases, the threshold value of temperature difference may remain consistent no matter what the measured temperature value may be. However, a lower measured temperature can affect the amount of leakage current encountered differently than a higher measured temperature. For example, the higher the measured temperature, the higher the leakage current encountered. Further, the increase in leakage current may not be linear and thus, to compensate for this non-linear leakage current value the threshold value of temperature difference may also be non-linear.

In some scenarios the measured temperature may closely match a temperature stored in the data structure 226 (e.g., as non-limiting examples, 1 degree, 2 degree, 3 degree differences, etc.). To compensate for the minimal difference between the measured temperature and the temperature value stored in the data structure 226, the measured temperature may be rounded to the nearest temperature value stored in the data structure 226. As an example, a temperature may be measured and determined to be 111 degrees. The measured temperature of 111 degrees may be compared to temperature values stored in the data structure 226. In the case where 111 degrees is not in the data structure 226 but a temperature value of 110 degrees is stored in the data structure 226, the power token allocation circuitry 213 may be configured to select the 110 degree temperature value in the data structure 226.

In other cases, when a difference in the temperature measured compared to a temperature stored in the data structure 226 is minimal or within a threshold value of temperature difference (e.g., 1 degree, 2 degree, 3 degree differences, etc.), the measured temperature may fall between two temperature values stored in the data structure 226. For example, a temperature value of 110 degrees and a temperature value of 115 degrees may both be stored in the data structure 226. In a scenario where the measured temperature is 112 degrees (i.e., a minimal difference of 2 degrees from the stored 110 degrees and a minimal difference of 3 degrees from the stored 115 degrees) interpolation may be implemented. For example, an interpolated value lying between 110 degrees and 115 degrees that closely matches a 112 degree temperature value may be calculated. As such, based on the utilization of interpolation for the measured temperature, the leakage current for a measured temperature of 112 degrees may be calculated.

As such, a voltage supplied and a measured temperature may match or closely match a voltage value and a temperature stored in the data structure 226. In the case where the voltage supplied closely matches, within a threshold value of voltage difference, and falls between two voltage values stored in the data structure 226 and the measured temperature closely matches, within a threshold value of temperature difference, and falls between two temperatures stored in the data structure 226, bidimensional interpolation may be utilized to calculate a leakage current value. Further, in a situation where the voltage supplied closely matches, within a threshold value of voltage difference, and falls outside of one voltage value stored in the data structure 226 and the measured temperature closely matches, within a threshold value of temperature difference, and falls between two temperatures stored in the data structure 226, a voltage value extrapolated from data in the data structure 226 that represents the voltage supplied and a temperature value interpolated from data in the data structure 226 that represents the measure temperature may be utilized to calculate the leakage current value.

In yet another case, a minimal difference (i.e., within a threshold value of temperature difference) in the measured temperature as compared to a temperature stored in the data structure 226 may result in the measured temperature falling just outside of one temperature value stored in the data structure 226. For example, temperature values of 110 degrees, 115 degrees, and 120 degrees may be stored in the data structure 226. In a case where the measured temperature is 122 degrees, the 122 degrees may not be stored in the data structure 226. However, the measured 122 degrees may be considered a minimal difference (within the threshold value of temperature difference) from the 120 degrees stored in the data structure 226. As such, extrapolation may be implemented to calculate a value corresponding to 122 degrees. As such, based on the utilization of extrapolation for the measured temperature, the leakage current for a temperature of 122 degrees may be calculated.

As previously described, a voltage supplied and a measured temperature may match or closely match a voltage value and a temperature stored in the data structure 226. In the case where the voltage supplied closely matches, within a threshold value of voltage difference, and falls between two voltage values stored in the data structure 226 and the measured temperature closely matches, within a threshold value of temperature difference, and falls outside of one temperature stored in the data structure 226, a voltage value interpolated from data in the data structure 226 that represents the voltage supplied and a temperature value extrapolated from data in the data structure 226 that represents the measure temperature may be utilized to calculate the leakage current value. Further, in a situation where the voltage supplied closely matches, within a threshold value of voltage difference, and falls outside of one voltage value stored in the data structure 226 and the measured temperature closely matches, within a threshold value of temperature difference, and falls outside of one temperature stored in the data structure 226, bidimensional extrapolation may be utilized to calculate a leakage current value.

In some cases, the data structure 226 may include zones of temperatures. The zones may be linear and include the same zone width. For example, 120 degrees-124 degrees may be a first zone, 115 degrees-119 degrees may be a second zone, 110 degrees-114 degrees may be a third zone, and so forth. As such, if the measured temperature is 112 degrees, the table corresponding to the 110 degree-114 degree zone (i.e., the third zone) may be selected in the data structure 226, or if the measured temperature is 122 degrees the table corresponding to the 120 degree-124 degree zone (i.e., the first zone) may be selected in the data structure 226, and so forth.

In some embodiments, the threshold value of temperature difference may be non-linear and may be based on a temperature range of the system 210. As an example, as voltages and temperatures in the system 210 change (e.g., increase or decrease), the leakage current may be non-linear. In various examples, when the non-linear leakage current is not taken into consideration during power allocation, the non-linear nature of the current leakage can contribute to the inefficient management of the resources of the system 210. Accordingly, to compensate for the non-linear leakage current encountered by the system 210 the threshold value of temperature difference may be non-linear. In the case where rounding, extrapolation, and/or interpolation may be implemented, a determination as to whether a difference between the measured temperature and a temperature stored in the data structure 226 is significant may vary based on the measured temperature. In a non-limiting example, a difference of 10 degrees at lower temperatures (e.g., temperatures between 25 degrees-88 degrees), in some cases, may not be considered significant. Whereas a difference of 10 degrees at higher temperatures (e.g., at and above 89 degrees), in some cases, may be considered significant. Further, in the case where zones are implemented, to compensate for the non-linear leakage current the zone widths may vary.

As an example, in the case of non-linear zones the threshold value of temperature difference for temperatures between (or a zone width of) 110-124 degrees may be set at 5 degrees (e.g., 120 degrees-124 degrees for a first zone, 115 degrees-119 degrees for a second zone, and 110 degrees-114 degrees for a third zone). The threshold value of temperature difference for temperatures between 89-109 degrees may be set at 7 degrees (e.g., 103 degrees-109 degrees for a fourth zone, 96 degrees-102 degrees for a fifth zone, and 89 degrees-95 degrees for a sixth zone). The threshold value of temperature difference for temperatures between 39-88 degrees may be set at 10 degrees (e.g., 79 degrees-88 degrees for a seventh zone, 69 degrees-78 degrees for an eighth zone, 59 degrees-68 degrees for a ninth zone, 49 degrees-58 degrees for a tenth zone, and 39 degrees-48 degrees for an eleventh zone). The threshold value of temperature difference for temperatures between 25-38 degrees may be set at 14 degrees (e.g., 25 degrees-38 degrees for a twelfth zone). The threshold value of temperature difference for temperatures below 25 degrees or at or above 125 degrees may be set at a different degree, though examples are not so limited and the threshold values and zones may be set at different degrees than discussed herein. Accordingly, a data structure 226 that includes all variations of potential supplied voltages and potential temperatures associated with the system 210 may include a table for each supplied voltage or voltage zone (linear or non-linear) where each table include a stored temperature or temperature zone (linear or non-linear). Further, each temperature associated with each supplied voltage (or each table), in the data structure 226 may include a measured leakage current and a date and time in which the temperature and the leakage current were measured, associated with the supplied voltage, and stored in the table.

As such, responsive to the measured temperature matching (i.e., closely matching) a stored temperature, the power token allocation circuitry 213 may be configured to, utilizing the data structure 226, determine a date and a time that the temperature was stored in the data structure 226 and compare the date and the time to a current date and a current time. The power token allocation circuitry 213 may determine whether the amount of time between the stored temperature date and time and the current date and time exceeds a threshold period. For example, the threshold period may be 1 week, 1 month, 3 months, 6 months, etc., and may be set dependent on variations of the system 210 (e.g., degradation of components of the system 210, scheduled or unscheduled workloads of the system 210, initial start-up of the system 210, etc.). The power token allocation circuitry 213 may be configured to, responsive to the date and time that the measured temperature was stored being within the threshold period in comparison to the current date and time, determine, utilizing the data structure 226, the associated leakage current and allocate a power token (or tokens) based on the amount of voltage supplied, the measured temperature, and the associated leakage current. In this scenario, the power token allocation circuitry 213 may utilize the stored leakage current associated with the stored voltage value corresponding to the amount of voltage supplied and the associated stored temperature corresponding to the measured temperature.

Put another way, the data structure 226 may include the plurality of temperatures corresponding to the plurality of voltages, the stored temperature may be one of the plurality of temperatures and the stored voltage may be one of the plurality of voltages, and the resource manager 229 may allocate the power token based on the one of the plurality of temperatures, the one of the plurality of voltages, and the associated leakage current. Further, as previously described, rounding, interpolation, and/or extrapolation may be implemented in the event that the measured temperature closely matches a temperature table in the data structure 226 and/or zones may be implemented in the event that the measured temperature falls within a zone. For example, the resource manager 229 may allocate the power token based on an extrapolation from one of the plurality of temperatures and/or one of the plurality of voltages. In the case where the measured temperature and/or the supplied voltage closely matches and is between two of the plurality of stored temperatures and/or two of the plurality of stored voltages, respectively, the resource manager 229 may allocate the power token based on an interpolation between two of the plurality of temperatures and/or two of the plurality of voltages. As such, the resource manager 229 may allocate the power token based on rounding, interpolation, extrapolation, and/or zones. However, in some cases, the temperature measured by the temperature sensor 223 may not be a temperature that is associated in the data structure 226 with the amount of voltage supplied. That is, the temperature measured may be significantly different than temperatures associated in the data structure 226 with the amount of voltage supplied. As used herein, a measured temperature may be considered significantly different than temperatures associated in the data structure 226 with an amount of voltage supplied when the measured temperature is outside of or greater than a threshold value of temperature difference from the temperatures associated in the data structure 226 with the amount of voltage supplied (e.g., a non-limiting example of a linear threshold value of temperature difference of 3 degrees, or a non-linear threshold value of temperature difference of 5 degrees, 7 degrees, 10 degrees, 14 degrees, etc.).

For example, during initial start-up or in early use of the system 210, the data structure 226 may lack a portion of or all associations between potential voltage amounts supplied to and potential temperatures measured in the system 210. As such, temperatures may not be associated to the potential voltage amounts supplied and/or stored temperatures may be significantly different than a measured temperature. Accordingly, the power token allocation circuitry 213 may be configured to drive the system 210 into an idle state responsive to an association between the amount of voltage supplied and the measured temperature. That is, responsive to the measured temperature being significantly different than temperatures stored in the data structure 226 (or different than temperatures associated with the voltage value stored in the data structure 226) or no temperatures being stored in the data structure 226, the power token allocation circuitry 213 may be configured to drive the system 210 into an idle state and determine the leakage current of the system 210.

While the system 210 is in the idle state, the current sensor 225 may measure leakage current. The power token allocation circuitry 213 may be configured to associate the amount of voltage supplied to the system 210 and the measured temperature with the measured leakage current and to store the measured leakage current associated with the amount of voltage supplied and the measured temperature and the current date and time in the data structure 226. The power token allocation circuitry 213 may be further configured to then drive the system 210 from the idle state into an operating state responsive to the measured leakage current being associated and stored in the data structure 226 with the amount of voltage supplied, the measured temperature, and the current date and time. The processor, the resource manager 229, and/or a combination thereof of the power token allocation circuitry 213, may be configured to then allocate a power token based on the amount of voltage supplied, the measured temperature, and the associated stored current.

In some cases, the temperature measured by the temperature sensor 223 may have been a temperature associated with (or closely matching) the amount of voltage supplied in the data structure 226 outside of the threshold period. For example, prior to initial start-up of the system 210, in some embodiments, default, worst-case scenario leakage currents, associated with particular temperatures and/or particular voltages, may be stored in the data structure 226. Further, a particular temperature may not have been encountered or measured by the system 210 while a particular voltage amount was being supplied, within the threshold period. As such, responsive to the amount of voltage supplied matching (or closely matching) a voltage value stored in the data structure 226 and the measured temperature matching (or closely matching) a stored temperature, the date and time that the measured temperature was associated with the amount of voltage supplied to the system 210 may be compared to the current date and time. Responsive to the measured temperature associated with the amount of voltage supplied being stored in the data structure 226 within the threshold period, the power token allocation circuitry 213 may be configured to refrain from driving the system 210 into an idle state. However, responsive to the date and time that the measured temperature was associated with the amount of voltage supplied to the system 210 and stored compared to the current date and time exceeding the threshold period, the power token allocation circuitry 213 may be further configured to drive the system 210 into an idle state and determine the leakage current of the system 210. The current sensor 225 may measure leakage current while the system 210 is in the idle state. The power token allocation circuitry 213 may be configured to associate the amount of voltage supplied to the system 210 and the measured temperature with the measured leakage current. The power token allocation circuitry 213 can store the measured leakage current associated with the amount of voltage supplied, the measured temperature, and the current date and time in the data structure 226. The power token allocation circuitry 213 may be further configured to drive the system 210 from the idle state into an operating state. The power token allocation circuitry 213 can allocate a power token based on the amount of voltage supplied, the measured temperature, and the associated stored leakage current.

In some embodiments, the power token allocation circuitry 213 may be further configured to monitor the temperature associated with the system 210. Responsive to a change (e.g., an increase or a decrease) in the measured temperature exceeding a threshold value of temperature change, the power token allocation circuitry 213 can determine whether the measured temperature (or a measured temperature closely matching in the case of rounding, calculated based on extrapolation and/or interpolation, or within a zone in the case of zones, etc.) corresponds to the amount of voltage supplied to the system 210 (or a voltage supplied closely matching in the case of rounding, calculated based on extrapolation and/or interpolation, or within a zone in the case of zones, etc.) in the data structure 226 and can determine a date and time that the measured temperature was associated with the amount of voltage supplied and stored in the data structure 226. As such, responsive to the measured temperature corresponding to the amount of voltage supplied to the system 210 in the data structure 226 and the date and time being within the threshold period, the power token allocation circuitry 213 may be further configured to allocate the power token based on the amount of voltage supplied, the measured temperature, and the associated stored leakage current.

The measured leakage current associated with the amount of voltage supplied and the measured temperature can be utilized by the power token allocation circuitry 213 to determine a quantity of static power tokens to allocate to the system 210 or a device of the system 210 to perform an operation. In some embodiments, since the total available power or the total power resource pool is made up of both static and dynamic power tokens, remaining power available for allocation can be allocated as dynamic power tokens. In some embodiments, a first portion of the remaining power available in the power resource pool may be designated as additional static power tokens and a second portion of the remaining power available in the power resource pool may be designated as dynamic power tokens. For example, as the amount of voltage supplied and/or measured temperature fluctuates causing changes in the leakage current, a quantity of static power tokens requested can fluctuate. The first portion of the remaining power available in the power resource pool can be reserved for a potential increase in request for static power tokens.

The leakage current (e.g., static current) can be determined. The leakage current can be converted to power tokens. For example, the leakage current can be converted to power using P=w/Δt. The wattage (e.g., W) can be calculated using W=Amp*Volt. A voltage of the system 210 can be utilized, together with the current, to determine a wattage. The wattage can be utilized with a time for which the resources are allocated to the device to determine a power (e.g., leakage power). The leakage power can be converted to power tokens.

The examples provided herein for calculating power tokens are exemplary and intended to cover multiple ways of calculating power tokens. In various instances, the power token allocation circuitry 213 can allocate less resources than a device requested. The device may run at a slower speed given that it was allocated less resources than the device requested as compared to a speed the device would have run if it was allocated the resources it requested. In some embodiments, the total power resource pool, allocated dynamic resources, and allocated static resources can be calculated at the power token allocation circuitry 213. In various instances, the total power resource pool can be calculated at the power token allocation circuitry 213 while the requested dynamic resources and the requested static resources are calculated at a device.

A device requesting a resource can provide a request to the power token allocation circuitry 213 for resources. As an example, the power token allocation circuitry 213 may receive a request for 30 power tokens. The power token allocation circuitry 213 can determine a quantity of tokens (e.g., dynamic and static) that can satisfy the 30 power tokens requested. For example, the power token allocation circuitry 213 may determine, based on a determined leakage current value, that 35 power tokens, including 30 dynamic and 5 static resources from the resource pool, can satisfy the request for 30 power tokens in view of the leakage current. The leakage can be determined to be 5 static power tokens. In this scenario, the resource manager 229 may allocate no less than 5 static power tokens. Accordingly, the 30 dynamic power tokens requested may be allocated by the resource manager 229. However, in the case where resources are low or prioritized between operations and/or devices of the system 210 by the power token allocation circuitry 213, the resource manager 229 may allocate fewer than the requested 30 dynamic power tokens or may take and reallocate power tokens allocated to a lower priority operation and/or device. In short, the device can request 30 tokens for dynamic resources and 5 tokens for static resources. The resource manager 229 can allocate between 5 and 35 power tokens dependent upon resources available and/or priority of resource allocation.

Further, in the described example where the device is a gated device, the device can request to un-gate (e.g., power on) and operate. The power token allocation circuitry 213 can determine the quantity of static power tokens assigned to operation(s) of the system 210 and/or devices of the system 210 and calculate the remaining dynamic power tokens left in the resource pool to determine whether there are sufficient static resources and dynamic resources for allocating power to the device. In the scenario where there are insufficient resources to un-gate the device, the power token allocation circuitry 213 can wait to allocate power tokens to un-gate the device until sufficient resources are available or can take and reallocate power tokens allocated to other operations and/or devices. As described, calculating the static resources and the dynamic resources used to fulfill the request for resources as opposed to allocating resources based on a worst-case scenario can allow for a more efficient utilization of resources.

In some embodiments, devices that calculate the static power tokens and/or request dynamic power tokens and static power tokens may be referred to as smart devices. The power token allocation circuitry 213 can receive the request from the device. The power token allocation circuitry 213, responsive to receiving the indication from a smart device that static power tokens are included in the requested power tokens, may refrain from calculating the static power tokens and may instead provide the power tokens that are requested if they are available. Calculating the static power tokens and the dynamic power tokens for requesting resources from the power token allocation circuitry 213 can remove computational and/or power demands from the system 210 (e.g., power token allocation circuitry 213) and can shift the computational and/or power demands to the devices that request resources. The power token allocation circuitry 213 can provide the requested power tokens to the device.

In various instances, the power token allocation circuitry 213 can, upon receipt of a request for resources, determine, in a number of non-limiting ways, whether the device is a smart device. For example, the request can include an indication that the static power tokens are included in the request for power tokens. In a number of examples, a first command can be utilized to request static power tokens and dynamic power tokens while a second command can be utilized to request dynamic power tokens. The first command can be utilized by smart devices while the second command is utilized by non-smart devices. A smart device is not limited to providing the first command but can provide the first command and/or the second command. The non-smart device can provide the second command but may not provide the first command.

Responsive to determining that the device that requested resources is a smart device, the power token allocation circuitry 213 can verify that the requested power tokens are available. Responsive to identifying that the requested power tokens are available, the power token allocation circuitry 213 can provide the power tokens to the requesting device.

Responsive to determining that the requesting device is a non-smart device, the power token allocation circuitry 213 can access the data structure 226. For example, an amount of voltage supplied can be determined by circuitry, such as is utilized in a processor, and a temperature associated with the system 210 can be measured and monitored by a temperature sensor 223 coupled to the processor. The voltage can be supplied by a voltage regulator 227 and a leakage current can be measured and monitored by a current sensor 225 coupled to the voltage regulator 227. When the amount of voltage supplied and measured temperature are associated with a leakage current in a data structure 226 coupled to the processor or closely match a voltage and temperature associated with the leakage current in the data structure 226, dependent on the date and time of the association, a resource manager 229 can allocate power tokens based on the leakage current associated with the amount of voltage supplied and the measured temperature. However, in a scenario where the amount of voltage supplied and the measured temperature are not associated with a leakage current in a data structure 226 of the power token allocation circuitry 213 or are significantly different than a voltage and/or a temperature associated with the leakage current in the data structure 226, or the amount of voltage supplied and the measured temperature were associated with a leakage current in a data structure 226 of the power token allocation circuitry 213 outside of the threshold period, the power token allocation circuitry 213 can drive the system 210 into an idle state. While in the idle state the current sensor 225 can be utilized to measure the leakage current and the power token allocation circuitry 213 can associate the measured leakage current to the amount of voltage supplied to and the temperature associated with the system 210 along with the current date and time. After the association, the power token allocation circuitry 213 can drive the system 210 back into an active state and the resource manager 229 can allocate power tokens based on the associated measured leakage current, the amount of voltage supplied, and the measured temperature. The resource manager 229 can allocate static power tokens based on the associated measured leakage current and dynamic power tokens based on the requirements of the requesting device and/or system 210, the power resources remaining in the total power resource pool after the quantity of allocated static power tokens are determined, and/or the priority of the requesting device and/or system 210.

By knowing an accurate static (e.g., leakage) current (e.g., current bias) at the temperatures and voltages, the power token allocation circuitry 213 can allocate power tokens with greater accuracy than allocating power tokens without calculating static currents. Allocating dynamic power tokens with greater accuracy, as opposed to allocating dynamic power tokens without accurately calculating the static current bias, can improve the overall performance of a system 210.

Although the examples described herein are given in the context of hardware circuitry, dynamic and static resources can be calculated utilizing computer readable instructions. In various instances, the calculation of the dynamic and static resources utilizing a data structure 226 can be performed by computer readable instructions which can be utilized to allocate resources.

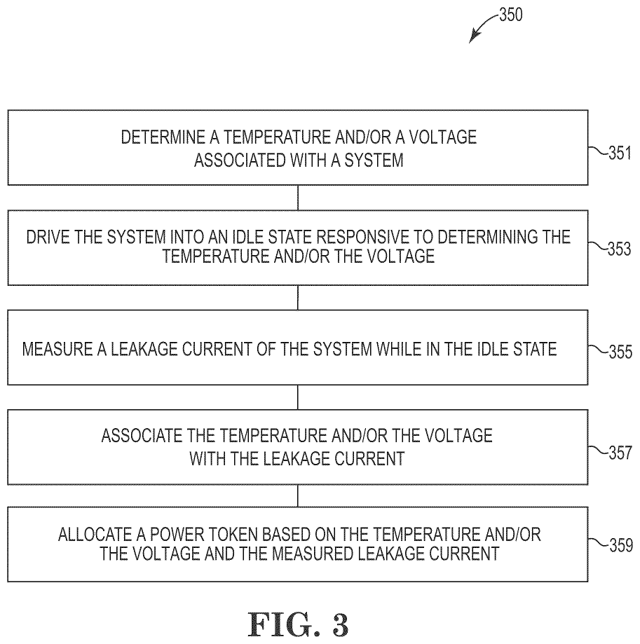

FIG. 3 illustrates an example method diagram 350 for power token allocation in accordance with some embodiments of the present disclosure. The method 350 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 350 is performed by the power token allocation 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

The method 350 includes managing resources by allocation of power tokens. The power token allocation circuitry 213 of FIG. 2 can receive a resource request from a device of the system. The device can be a device that is internal to the system or that is coupled to the system through a bus or a communication channel, for example. The resource request can include a request for power resources expressed as power tokens. A resource manager 229 of FIG. 2 of the system can allocate power tokens to the device to perform a task or tasks associated with the device. Both static and dynamic power tokens can be allocated from a total power resource pool that can include a plurality of static and dynamic power tokens utilized for power allocation to different devices of the system. As previously described, as power is transferred to the system (or a device of the system) a portion of the electric current transferred can leak (i.e., leakage current). This leakage power becomes unavailable to the device for performing operations. The static power tokens can represent this power that becomes unavailable. As described herein, resources can be managed utilizing a data structure 226 of FIG. 2. To compensate for the leakage current, the power token allocation circuitry can utilize the data structure to determine the leakage current of the system at a particular voltage and a particular temperature.

For example, at operation 351, the power token allocation circuitry can determine a voltage supplied to and a temperature associated with a system. For example, the power token allocation circuitry may be coupled to a voltage regulator 227 of FIG. 2. The voltage regulator can supply voltage to the system. The power token allocation circuitry may be configured to compare the amount of voltage supplied to the system to voltage values stored in the data structure. Voltage amounts supplied to the system may have a table in the data structure associated with the voltage supplied (e.g., a specific voltage value table such as a 0.74V table or a voltage zone such as a 0.74V-0.76V table, etc.). In some embodiments, responsive to the request for resources, the voltage measurements can be accessed in the data structure by the power token allocation circuitry.

Further, the power token allocation circuitry can be coupled to a temperature sensor 223 of FIG. 2 (or multiple temperature sensors). The temperature sensor can be utilized to measure and/or monitor a temperature associated with a system 210 of FIG. 2. In some embodiments, the temperature sensor may perform a number of operations on the measured temperature(s) including taking a number of measurements of the temperature and averaging the temperature prior to providing the temperature to the power token allocation circuitry.

At operation 353, the power token allocation circuitry can drive the system into an idle state responsive to determining the voltage supplied to and the temperature of the system. For example, the power token allocation circuitry can determine whether the voltage associated with the system and the temperature of the system are stored in the data structure (or closely matches what is stored in the data structure in the case of rounding, can be calculated based on extrapolation and/or interpolation, or are within a zone in the case of zones, etc.). Responsive to the voltage supplied and the measured temperature being in the data structure (or closely matching in the case of rounding; calculable in the case of extrapolation and/or interpolation; or being within a voltage zone and a temperature zone, respectively, in the case of zones), the power token allocation circuitry can determine whether a date and time in which the voltage supplied and the measured temperature were stored in the data structure exceeds a threshold period. Responsive to the voltage supplied and/or the measured temperature not stored in the data structure or the date and time exceeding the threshold period, the power token allocation circuitry can drive the system into the idle state.

At operation 355, the power token allocation circuitry can determine a leakage current of the system while the system is in the idle state. As previously described, responsive to the voltage supplied and/or the measured temperature not stored in the data structure or the date and time exceeding the threshold period, the power token allocation circuitry can drive the system into the idle state. Once in the idle state, a leakage current measurement can be performed. Put another way, responsive to the voltage supplied and/or the measured temperature not stored in the data structure (as previously described) or the date and time exceeding the threshold period, the power token allocation circuitry can drive the system into the idle state to measure the leakage current.

For example, the power token allocation circuitry can be coupled to a current sensor 225 of FIG. 2. The current sensor can be utilized to measure the leakage current of the system. In some embodiments, multiple current sensors may be utilized to monitor leakage current throughout the system (e.g., measuring leakage current to different devices).

At operation 357, the power token allocation circuitry can associate the voltage supplied and the measured temperature with the leakage current. For example, the power token allocation circuitry can be coupled to the data structure. The voltage supplied and the measured temperature can be associated with the measured leakage current and the power token allocation circuitry can store the voltage supplied, the measured temperature, the measured leakage current, and a current date and time associated with the voltage supplied, the measured temperature, and the measured leakage current in the data structure. The voltage supplied, the measured temperature, the measured leakage current, and the date and time can be stored in a table in the data structure. As such, the power token allocation circuitry may determine, associate, and store the amount of voltage supplied to the system, the measured temperature associated with the system, and the measured leakage current and date and time associated with the amount of supplied voltage and the measured temperature.

At operation 359, the power token allocation circuitry can allocate a power token based on the voltage supplied, the measured temperature, and the stored leakage current. For example, the power token allocation circuitry can be coupled to the resource manager. The resource manager can allocate static power tokens based on the leakage current. Utilized static power tokens can be deducted from the total power resource pool to determine available dynamic power tokens. Accordingly, available dynamic power tokens can be determined and allocated based on the voltage supplied, the measured temperature, and the stored leakage current. Further, resources can be re-allocated from dynamic to static and vice versa, as utilized by the power token allocation circuitry.

Further, responsive to the voltage supplied and the measured temperature being stored in the data structure (or closely matches what is stored in the data structure in the case of rounding, being calculable based on extrapolation and/or interpolation, or being within a voltage zone and a temperature zone, respectively, etc.) and the date and time being within the threshold period, the power token allocation circuitry can refrain from driving the system into the idle state. The power token allocation circuitry can determine, from the data structure, the leakage current associated with the voltage supplied and the measured temperature. The power token allocation circuitry can determine, based on the associated leakage current, allocation of static power tokens.

Accordingly, the power token allocation circuitry, responsive to the date and time the voltage associated with the system and the measured temperature being stored in the data structure within the threshold period, can allocate the power token based on the voltage and the temperature stored in the data structure and the associated leakage current. Put another way, the power token allocation circuitry, responsive to a date and time the measured temperature was associated with the amount of voltage supplied to the system being stored in the data structure within the threshold period, can allocate the power token based on the amount of voltage supplied, temperature stored in the data structure, and the associated leakage current. As such, to compensate for the leakage current, the power token allocation circuitry can utilize the data structure to determine the leakage current of the system at a particular voltage and a particular temperature. The power token allocation circuitry can determine static power tokens to be utilized based on the leakage current associated to the particular voltage and particular temperature stored in a table in the data structure.

Utilized static power tokens can be deducted from the total power resource pool to determine available dynamic power tokens. For example, since the total available power or the total power resource pool is made up of both static and dynamic power tokens, remaining power available for allocation can be allocated as dynamic power tokens. Accordingly, available dynamic power tokens can be determined and allocated based on the temperature and/or the voltage and the associated leakage current. Further, resources can be re-allocated from dynamic to static and vice versa, as utilized by the power token allocation circuitry. For example, the power token allocation circuitry may designate a first portion of the remaining power available of the power resource pool to static power tokens to compensate for fluctuations (e.g., voltage and/or temperature fluctuations) within the system and designate a second portion of the remaining power available of the power resource pool to dynamic power tokens. Dynamic power tokens can represent power that is available to the device for performing operations (e.g., read/write operations, logical operations, network operations, matrix operations, machine learning operations, etc.).

In various instances, the static resources can be reclassified as dynamic resources and/or the dynamic resources can be reclassified as static resources. For instance, as the temperature and/or voltage of the system changes, the static resources can be reclassified as dynamic resources and/or the dynamic resources can be reclassified as static resources.

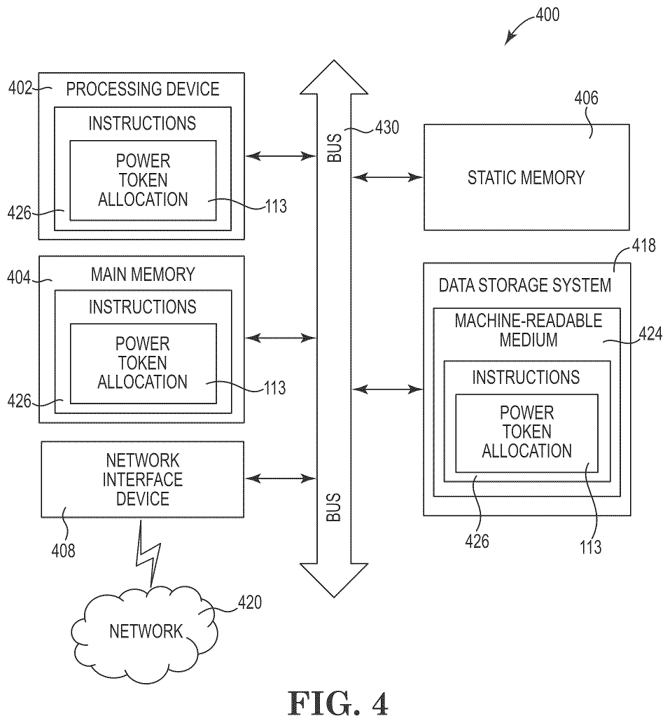

FIG. 4 is a block diagram of an example computer system 400 in which embodiments of the present disclosure may operate. For example, FIG. 4 illustrates an example machine of a computer system 400 within which a set of instructions, for causing the machine to perform any one or more of the methodologies discussed herein, can be executed. In some embodiments, the computer system 400 can correspond to a host system (e.g., the host system 120 of FIG. 1) that includes, is coupled to, or utilizes a memory system (e.g., the memory system 110 of FIG. 1) or can be used to perform the operations of a controller (e.g., to execute an operating system to perform operations corresponding to the power token allocation circuitry 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 400 includes a processing device 402, a main memory 404 (e.g., read-only memory (ROM), flash memory, dynamic random access memory (DRAM) such as synchronous DRAM (SDRAM) or Rambus DRAM (RDRAM), etc.), a static memory 406 (e.g., flash memory, static random access memory (SRAM), etc.), and a data storage system 418, which communicate with each other via a bus 430.

The processing device 402 represents one or more general-purpose processing devices such as a microprocessor, a central processing unit, or the like. More particularly, the processing device 402 can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 402 can also be one or more special-purpose processing devices such as an application specific integrated circuit (ASIC), a field programmable gate array (FPGA), a digital signal processor (DSP), network processor, or the like. The processing device 402 is configured to execute instructions 426 for performing the operations and steps discussed herein. The computer system 400 can further include a network interface device 408 to communicate over the network 420.

The data storage system 418 can include a machine-readable storage medium 424 (also known as a computer-readable medium) on which is stored one or more sets of instructions 426 or software embodying any one or more of the methodologies or functions described herein. The instructions 426 can also reside, completely or at least partially, within the main memory 404 and/or within the processing device 402 during execution thereof by the computer system 400, the main memory 404 and the processing device 402 also constituting machine-readable storage media. The machine-readable storage medium 424, data storage system 418, and/or main memory 404 can correspond to the memory system 110 of FIG. 1.

In one embodiment, the instructions 426 include instructions to implement functionality corresponding to power token allocation (e.g., the power token allocation circuitry 113 of FIG. 1). While the machine-readable storage medium 424 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read-only memory (“ROM”), random access memory (“RAM”), magnetic disk storage media, optical storage media, flash memory devices, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method, comprising:
determining a temperature associated with a system;
driving the system into an idle state responsive to determining the temperature;
measuring a leakage current of the system while in the idle state;
associating the temperature with the measured leakage current; and
allocating a power token based on the temperature and the measured leakage current.

2. The method of claim 1, wherein the method includes allocating a static power token, a dynamic power token, or a combination thereof.

3. The method of claim 1, further comprising storing the temperature, the measured leakage current, and a current date and time associated with the temperature and the measured leakage current in a data structure.

4. The method of claim 1, further comprising:
determining whether the temperature associated with the system is stored in a data structure; and
responsive to the temperature not being stored in the data structure, driving the system into the idle state to measure the leakage current.

5. The method of claim 1, further comprising:
determining whether the temperature associated with the system is in a data structure;
responsive to the temperature being in the data structure, determining whether a date and time in which the temperature was stored in the data structure exceeds a threshold period; and
responsive to the date and time exceeding the threshold period, driving the system into the idle state to measure the leakage current.

6. The method of claim 5, wherein responsive to the date and time being within the threshold period, refraining from driving the system into the idle state.

7. The method of claim 5, wherein responsive to the date and time being within the threshold period, allocating the power token based on the temperature stored in the data structure and a leakage current associated with the temperature stored in the data structure.

8. An apparatus, comprising:
a voltage regulator to regulate an amount of voltage supplied to a system;
a temperature sensor to measure a temperature associated with the system;
a current sensor to measure a leakage current of the system while the system is in an idle state;
a circuitry coupled to the voltage regulator, the temperature sensor, and the current sensor, wherein the circuitry is configured to:
associate the amount of voltage supplied and the measured temperature with the measured leakage current; and
store the measured leakage current associated with the amount of voltage supplied and the measured temperature and a current date and time in a data structure; and
a resource manager to allocate a power token based on the amount of voltage supplied, the measured temperature, the measured leakage current, and the current date and time stored in the data structure.

9. The apparatus of claim 8, wherein:
the data structure includes a plurality of temperatures corresponding to a plurality of voltages;
the stored temperature is one of the plurality of temperatures and the stored voltage is one of a plurality of voltages; and
the resource manager is to allocate the power token based on the one of the plurality of temperatures and the one of the plurality of voltages.

10. The apparatus of claim 8, wherein the circuitry is further configured to:
compare the amount of voltage supplied to the system to voltage values stored in the data structure;
responsive to the amount of voltage supplied matching a voltage value stored in the data structure, compare the measured temperature to temperatures associated with the voltage value stored in the data structure; and
responsive to the measured temperature matching a stored temperature:
determine a date and time that the stored temperature was stored; and
responsive to the date and time being within a threshold period, allocate a power token based on the amount of voltage supplied, the measured temperature, and the stored leakage current.

11. The apparatus of claim 10, wherein responsive to the measured temperature being different than the temperatures stored in the data structure the circuitry is further configured to:
drive the system into the idle state for measurement of the leakage current;
determine the measured leakage current of the system;
associate the amount of voltage supplied to the system and the measured temperature with the measured leakage current;
store the measured leakage current associated with the amount of voltage supplied and the measured temperature and the current date and time in the data structure; and
allocate a power token based on the amount of voltage supplied, the measured temperature, and the stored leakage current.

12. The apparatus of claim 10, wherein responsive to the date and time that the stored temperature was stored exceeding the threshold period the circuitry is further configured to:
drive the system into the idle state for measurement of the leakage current;
determine the measured leakage current of the system;
associate the amount of voltage supplied and the measured temperature with the measured leakage current;
store the measured leakage current associated with the amount of voltage supplied and the measured temperature and the current date and time in the data structure; and
allocate the power token based on the amount of voltage supplied, the measured temperature, and the stored leakage current.

13. The apparatus of claim 8, wherein the processor is further configured to:
monitor the voltage supplied to the system to detect a change in the amount of voltage supplied;
determine whether a detected change in the amount of voltage supplied exceeds a threshold value of voltage change; and
responsive to determining that the change in the amount of voltage supplied exceeds the threshold value:
compare the amount of voltage supplied to the system to voltage values stored in the data structure;
responsive to the amount of voltage supplied matching a voltage value stored in the data structure, compare the measured temperature to temperatures associated with the voltage value stored in the data structure; and
responsive to the measured temperature matching a stored temperature and a date and time that the measured temperature was stored being within a threshold period, allocate the power token based on the amount of voltage supplied, the measured temperature, and the stored leakage current.

14. The apparatus of claim 8, wherein the processor is further configured to monitor the temperature associated with the system and responsive to a change in the measured temperature exceeding a threshold value of temperature change:
determine whether the measured temperature corresponds to the amount of voltage supplied to the system in the data structure and a date and time that the measured temperature was associated with the amount of voltage supplied and stored in the data structure; and
responsive to the measured temperature corresponding to the amount of voltage supplied to the system in the data structure and the date and time being within a threshold period, allocate a power token based on the amount of voltage supplied, the measured temperature, and the associated leakage current.

15. The apparatus of claim 14, wherein the threshold value of temperature change and a threshold value of voltage change are non-linear and based on a temperature range and a voltage range of the system, respectively.

16. A system comprising:
a voltage regulator to regulate an amount of voltage supplied to the system;
a temperature sensor to measure a temperature associated with the system;
a current sensor to measure a leakage current of the system;
a circuitry coupled to the voltage regulator, the temperature sensor, and the current sensor, wherein the circuitry is configured to:
drive the system into an idle state responsive to an association between the amount of voltage supplied and the measured temperature, wherein while in the idle state the circuitry is further configured to:
determine the measured leakage current of the system;
associate the amount of voltage supplied and the measured temperature with the measured leakage current; and
store the measured leakage current associated with the amount of voltage supplied and the measured temperature and a current date and time in a data structure; and
a resource manager to allocate a power token based on the amount of voltage supplied, the measured temperature, and the stored leakage current.

17. The system of claim 16, wherein the circuitry is further configured to:
compare the amount of voltage supplied to voltage values stored in the data structure;
responsive to the amount of voltage supplied matching a voltage value stored in the data structure, compare the measured temperature to temperatures associated with the voltage value stored in the data structure; and
drive the system into the idle state responsive to the measured temperature being different than the temperatures associated with the voltage value stored in the data structure.

18. The system of claim 16, the circuitry is further configured to:
compare the amount of voltage supplied to voltage values stored in the data structure;
responsive to the amount of voltage supplied matching a voltage value stored in the data structure, compare the measured temperature to temperatures associated with the voltage value stored in the data structure;
responsive to the measured temperature matching a stored temperature, compare a date and time that the measured temperature was associated with the amount of voltage supplied to the system to the current date and time; and
drive the system into the idle state responsive to a difference between the date and time and the current date and time exceeding a threshold period.

19. The system of claim 18, wherein the circuitry is further configured to, responsive to the amount of voltage supplied matching a voltage value stored in the data structure, the measured temperature matching a stored temperature, and the difference between the date and time and the current date and time being within a threshold period, refrain from driving the system into the idle state.

20. The system of claim 18, wherein the circuitry is further configured to drive the system from the idle state into an operating state responsive to the measured leakage current being associated and stored in the data structure with the amount of voltage supplied, the measured temperature, and the current date and time.
